(19) United States
(12) Patent Application Publication
(10) Pub. No.: US 2025/0258429 A1
(43) Pub. Date: Aug. 14, 2025

(54) METHOD OF MANUFACTURING RESIST

(71) Applicant: Kioxia Corporation, Tokyo (JP)

(72) Inventors: Hiroshi TOMITA, Muko Kyoto (JP); Yusuke OSHIMA, Yokkaichi Mie (JP)

(73) Assignee: Kioxia Corporation, Tokyo (JP)

(21) Appl. No.: 18/990,496

(22) Filed: Dec. 20, 2024

(30) Foreign Application Priority Data
Feb. 14, 2024 (JP) 2024-020669
Aug. 9, 2024 (JP) 2024-134182

(51) Int. Cl. G03F 7/004

(52) U.S. Cl. CPC G03F 7/004

(57) ABSTRACT

A method of manufacturing a resist according to an embodiment includes obtaining a resist mixture by mixing a raw material of the resist in a mixing vessel; repeating delivering the resist mixture from a bottom of the mixing vessel to an inlet of a filter, the filter including the inlet and an outlet; filtering the resist mixture using the filter; and delivering the filtered resist mixture from the outlet to the mixing vessel; obtaining a first mixture by mixing the resist mixture and a predetermined first solution, the resist mixture being obtained from between the bottom and the inlet; measuring first defects of the first mixture; obtaining a second mixture by mixing the resist mixture and the predetermined first solution, the resist mixture being obtained from between the outlet and the mixing vessel; measuring second defects of the second mixture; and comparing the first defects and the second defects.

### CROSS-REFERENCE TO RELATED APPLICATION

This application is based upon and claims the benefit of priority from Japanese Patent Application No. 2024-020669, filed on Feb. 14, 2024, and Japanese Patent Application No. 2024-134182, filed on Aug. 9, 2024, the entire contents of which are incorporated herein by reference.

### FIELD

Embodiments described herein relate generally to method of manufacturing resist.

### BACKGROUND

Various solutions are used in manufacturing process of semiconductor device fabrication process. Resists (photoresists), which are liquids particularly used in lithography processes, include defects, such as bubbles, metallic particles, and other particles. The presence of the defects causes various problems in the patterning process (a resist coating process, a light exposure process, and a development process) and leads to poor device geometry in microfabrication of the semiconducting device. As a result, the yield of the semiconductor device decreases. Therefore, the defects are removed in a resist manufacturing process (a process of mixing a resist resin, an additive, a solvent, a photosensitive agent, and the like, and a process of filling a resist into a shipping container), a patterning process at a device manufacturer, and specifically, a process of applying a resist onto a semiconductor wafer (spin-coating device), by circulating filtration in which the resist is passed through a filter for a liquid.

### BRIEF DESCRIPTION OF THE DRAWINGS

FIGS. 1 A-B are schematic diagrams describing light scattering behavior from a light scatterer in the resist solution in measuring the defects in the resist solution in a comparative embodiment.

FIG. 2 is a schematic diagram of the method of manufacturing the resist according to the first embodiment.

FIG. 3 is a schematic diagram explaining how to measure the defects in the resist solution of the first embodiment.

FIGS. 4 A-B are schematic diagrams of the defect detecting cell of the first embodiment.

FIG. 5 is an example of evaluating the liquid including the defects performed using the defect detecting cell of the first embodiment.

FIGS. 6 A-E are another example of evaluating the liquid including the defects performed using the defect detecting cell of the first embodiment.

FIGS. 7 A-E are another example of evaluating the liquid including the defects performed using the defect detecting cell of the first embodiment.

FIG. 8 is a diagram explaining the scattered light strength of the light background that varies according to the ratio of the solution X added to the resist solution of the first embodiment.

FIG. 9 is an example indicating the circulation time dependence of the number of the filtered secondary defects of the defects of the first embodiment. (when the filtered secondary defects decrease monotonically)

FIG. 10 is an example indicating the circulation time dependence of the number of the filtered secondary defects (metal particle defects A) of the resist defects of the first embodiment. (when the filtered secondary metal particle defects A stops in the middle of the reduction and the number of defects saturates.)

FIG. 11 is an example indicating the circulation time dependence of the number of the filtered secondary defects (total number of the bubbles B, the number of particles D differing from the bubbles B and the metallic particles A) of the first embodiment.

FIGS. 12 A-D are the mix-ratio dependence of the resist mixture and a predetermined solution X, as measured by FPT method.

FIG. 13 is a schematic diagram explaining how to measure the defects in the resist solution of a second embodiment.

FIG. 14 is an example of evaluating the liquid including the defects performed using the defect detecting cell of the second embodiment.

FIG. 15 is an example of evaluating the liquid including the defects performed using the second defect measuring instrument 318 of the second embodiment.

FIG. 16 is a schematic diagram explaining how to measure the defect in the resist solution according to another aspect of the second embodiment.

FIG. 17 is a schematic diagram of a method of manufacturing the resist according to a third embodiment.

FIG. 18 is a schematic diagram of a method of manufacturing the resist according to the third embodiment.

### DETAILED DESCRIPTION

A method of manufacturing a resist according to an embodiment includes obtaining a resist mixture by mixing a raw material of the resist in a mixing vessel; repeating delivering the resist mixture from a bottom of the mixing vessel to an inlet of a filter, the filter including the inlet and an outlet; filtering the resist mixture using the filter; and delivering the filtered resist mixture from the outlet to the mixing vessel; obtaining a first mixture by mixing the resist mixture and a predetermined first solution, the resist mixture being obtained from between the bottom and the inlet; measuring first defects of the first mixture; obtaining a second mixture by mixing the resist mixture and the predetermined first solution, the resist mixture being obtained from between the outlet and the mixing vessel; measuring second defects of the second mixture; and comparing the first defects and the second defects.

Hereinafter, embodiments will be described with reference to the diagrams. In addition, in the diagrams, the same or similar elements are denoted by the same or similar reference numerals.

### First Embodiment

In order to explain the first embodiment, the comparative embodiment is described firstly.

First, a method of manufacturing the resist according to the comparative embodiment will be described. Here, the evaluation method of the defects in the resist solution used in the method of manufacturing the resist will be described. The evaluation method of the defects is a method for evaluating the presence or absence of the light scatterer as the presence or absence of the defects in a resist solution by using a light scattering method (particle measurement in the liquid:a Liquid particle counter:LPC (the light scattering method)). More specifically, the evaluation method of the defects uses the light scatter strength of the light scatterer to measure the size of the defects with the measuring instrument. Calibration of such a measuring instrument is performed using the light scatter strength of the standard particles. Here, as the standard particles, for example, polystyrene latex particles having different sizes are used.

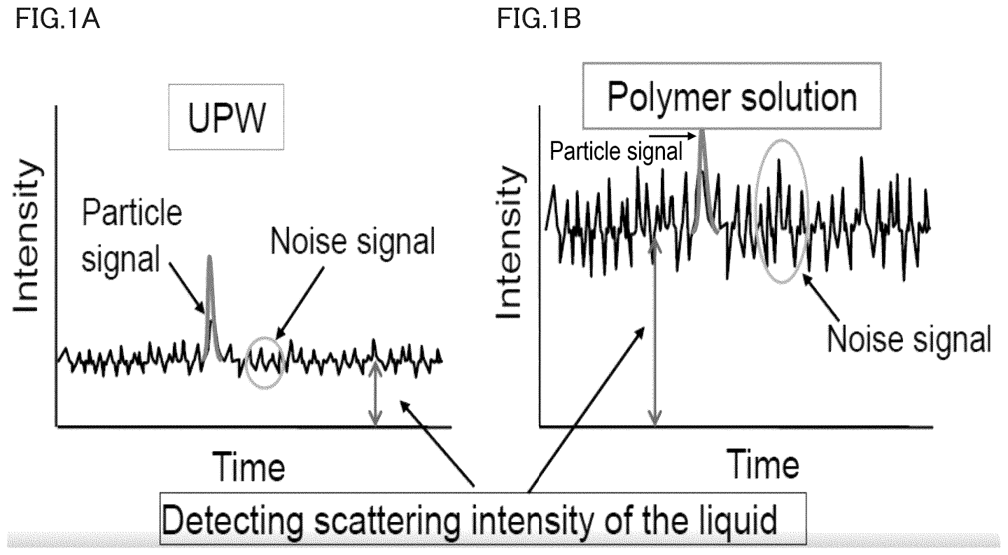

FIGS. 1 A-B are the schematic diagrams describing light scattering behavior from the light scatterer in the resist solution in measuring the defects in the resist solution in the comparative embodiment.

This method, for example, uses the phenomenon that the defects in the resist solution, such as “metal particles A”, “the bubbles B”, “particles D differing from the bubbles B and the metal particles A”, “cluster defects E”, and the like, are light scattered with respect to the irradiated laser light (intensity). If the signal-to-noise ratio (S/N ratio) of the intensity of the scattered light from the liquid without the light scatterer is adequate, this intensity is used as the defect measurement in the resist solution.

Specifically, the comparative embodiment is a technique for measuring the defects of 1000 nm superclass, such as the giant bubbles B, the giant metal particles A, and the cluster defects E, which exceed 100 nm (0.1 μm), with respect to the scattered strength from the resist solution, including the high polymer resin C and the cluster defects E.

In the resist solution, the high polymer resin C is present at a concentration of several percent in the organic solvent. Therefore, the background scattered light is measured together with the photosensitizer and the additive, which are other components dissolved in the organic solvent.

However, in addition to the above, in the resist solution, there are non-target defects such as “the metal particles A”, “the bubbles B”, and “the particles D which differ from the bubbles B and the metal particles A”, which are the defects. Reducing these out-of-purpose defects is an important task in the resist manufacturing process.

The reason for this is as follows. That is, in the resist solution, the organic molecular components such as the high polymer resin C, the photosensitive agent, and the additive, which are present at a concentration of several percent, and the metal particles A, the bubbles B, and the particles D which differ from the bubbles B and the metal particles A, which are impurities of the resist, are mixed. There are “cluster defects E” in which “the high polymer resin C”, “the metal particles A”, and “the particles D which differ from the bubbles B and the metal particles A” are clustered. The cluster defects E, in which organic components and impurities are aggregated, are responsible for the increase in the defects when the resist solution is left for storage. In addition, the cluster defects E are large contributors for increasing the background scattered light.

Here, “the metal particle A” are silver, gold, iron hydroxide oxide, or chromium oxide particles. Here, “the particles D which differ from the metal particles A” are, for example, particles of carbon, silica (quartz) or fluoropolymer.

In the present embodiment, in order to eliminate the background scattered light from the cluster defects E, an organic solvent X that dissolves the cluster defects E is added to the resist solution. Thereby, true defects in the resist solution (“the metal particles A”, “the particles D which differ from the metal particles A and the bubbles”) are detected.

The defects are preferably detected by, for example, a Flow Particle Tracking (FPT) method using the light scattering principles. This is because minute defects can be detected. However, the defects can be detected by other methods. For example, the defects can be detected by a single particle ICP-MS method (spICP-MS method).

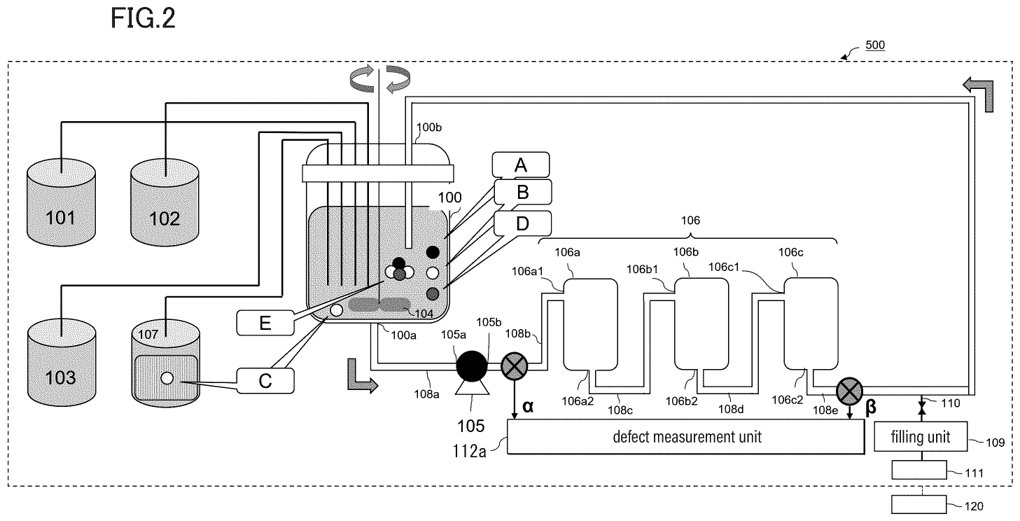

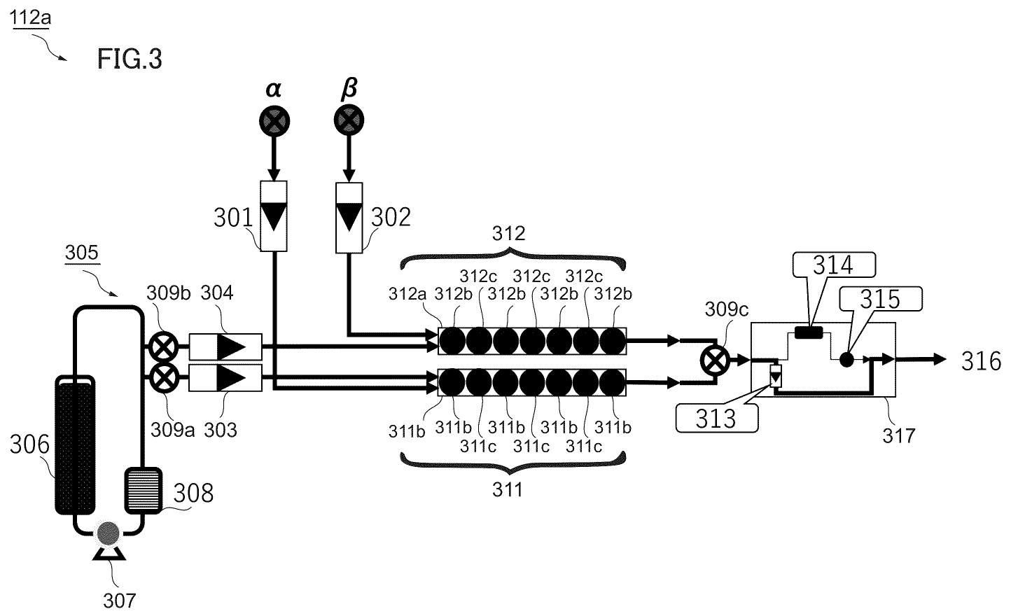

A part of the schematic diagram of the method of manufacturing the resist for describing the present embodiment is shown in FIG. 2. In other words, FIG. 2 is the schematic diagram of the resist manufacturing device 500 of the present embodiment.

A container 101 for storing a resist solvent, a container 107 for storing the high polymer resin, a container 102 for storing the photosensitive agent, and a container 103 for storing the additive are connected to the mixing vessel 100. Here, the resist solution, the high polymer resin, the photosensitizer, and the additive are input into the mixing vessel 100. For example, the resist solvent, then the high polymer resin C, then the photosensitizer, and finally the additive are input into the mixing vessel 100. The mixing vessel 100 is a container made of SUS, for example, with a fluoropolymer-coated inside. However, the mixing vessel 100 is not particularly limited thereto.

The high polymer resin C contains, for example, at least one compound selected from the group consisting of pyrazine-based, thiophene-based, fullerene-based, adamantane-based, heterocyclic ring system, and fluorinated system, which are photosensitive materials used for g-lines, i-lines, KrF, ArF, and the like.

In addition, the high polymer resin C contains at least one compound selected from the group consisting of a bromine compound, a halogen compound containing an iodine compound and a fluorine compound, and phenols, which are photosensitive materials used in EUV (Extreme ultraviolet lithography).

Next, the raw material of the resist containing the resist solvent, the high polymer resin C, the photosensitive agent, and the additive are stirred and mixed using the mixer 104 installed in the mixing vessel 100. As a result, the resist mixture containing the resist solvent, the high polymer resin C, the photosensitive agent 102, and the additive 103 are obtained. Here, the mixer 104 is, for example, a stirring blade made of PTFE (polytetrafluoroethylene). However, the mixer 104 is not particularly limited thereto.

From the bottom 100a of the mixing vessel 100, the resist mixture is then delivered to the filter 106 using a fluid aspiration discharge pump 105. Here, the high polymer resin C, the photosensitive agent 102, the additive 103, and the like contained in the resist mixture stay in the lower part of the mixing vessel 100 due to gravitational force. The resist mixture is therefore withdrawn from the bottom 100a of the mixing vessel 100.

The resist mixture is filtered by the filter 106.

The filter 106 includes, for example, the filter 106a, the filter 106b, and the filter 106c. The filter 106a, the filter 106b, and the filter 106c are connected in series with each other, for example. In the present embodiment, the number of the filter used is three. However, the number of the filter is not limited to three. For example, the filter 106a, the filter 106b, and the filter 106c have different types of membranes used therein. Depending on the type of the defects to be filtered and the number of the defects required for the resist mixture, the type, the number, and the order of connecting the filter to be combined can be changed as appropriate.

Here, for example, the bottom 100a of the mixing vessel 100 and the inlet 105a of the fluid aspiration discharge pump 105 are connected by a pipe 108a. The outlet 105b of the fluid aspiration discharge pump 105 and the inlet 106al of the filter 106a are connected by a pipe 108b. The outlet 106a2 of the filter 106a and the inlet 106b1 of the filter 106b are connected by the pipe 108c. The outlet 106b2 of the filter 106b and the inlet 106cl of the filter 106c are connected by the pipe 108d. The resist mixture discharged from the outlet 106c2 of the filter 106c is returned to the mixing vessel 100 by the pipe 108e. In this way, the resist mixture is circulated and filtered by the filter 106 a plurality of times.

The resist mixture that has been sufficiently defect-filtered by the filter 106 is filled into container 111 using the filling unit (filler) 109 connected to the pipe 108e via the pipe 110. The container 111 is, for example, a container for shipping the resist mixture.

For example, the inlet 106al of the filter 106 is provided on the upper part of the filter 106a. For example, the outlet 106a2 of the filter 106 is provided on the lower part of the filter 106a. The high polymer resin C, the photosensitive agent 102, the additive 103, and the like contained in the resist mixture move from the upper part of the filter 106a toward the bottom part of the filter by gravitational force. Therefore, by arranging the inlet 106al and the outlet 106a2 of the filter 106a as described above, filtering is efficiently performed. The same applies to the filter 106b and the filter 106c.

Then, the resist mixture is acquired from the acquisition port α provided at the pipe 108b between the outlet 105b of the fluid aspiration discharge pump 105 and the inlet 106al of the filter 106a (between the bottom 100a of the mixing vessel 100 and the inlet 106al of the filter 106a).

In addition, the resist mixture is acquired from the acquisition port β provided at the pipe 108e between the outlet 106c2 of the filter 106c and the mixing vessel 100.

The controller 120 performs, for example, input of the resist solvent from the container 101 to the mixing vessel 100, input of the high polymer resin C from the container 107 to the mixing vessel 100, input of the photosensitive agent from the container 102 to the mixing vessel 100, input of the additive from the container 103 to the mixing vessel 100, stirring and mixing in the mixing vessel 100 using the mixer 104, on/off of the fluid aspiration discharge pump 105, control of acquisition of the resist mixture from the acquisition port α and the acquisition port β, control of the first defect measurement unit (measurer) 112a, control of the filling unit 109, and the like.

The controller 120 is, for example, an electronic circuit. The controller 120 is, for example, a computer composed of a combination of hardware such as an arithmetic circuit and software such as a program.

Here, the types and numbers of the defects are measured for the resist mixture acquired from the acquisition port α and the resist mixture acquired from the acquisition port β using the first defect measurement unit 112a. Then, the defects of the resist mixture acquired from the acquisition port α and the defects of the resist mixture acquired from the acquisition port β are compared.

For example, if the difference obtained by subtracting the number of the first defects from the number of the second defects is less than or equal to the first predetermined value, the process of repeating the steps of delivering the resist mixture from the bottom 100a of the mixing vessel 100 to the filter 106, filtering the resist mixture, and delivering the filtered resist mixture to the mixing vessel, may be stopped. This is because if the difference obtained by subtracting the number of the second defects from the number of the first defects is less than or equal to the first predetermined value, the defect of the resist mixture is considered to be sufficiently reduced. Note that such an operation can be performed using the controller 120, for example.

The filtered resist mixture may then be filled into the container 111 using a filling unit 109 connected to the pipe 108e from the outlet of the filter 106 via the pipe 110.

FIG. 3 is the schematic diagram explaining how to measure the defects in the resist solution of the present embodiment. FIG. 3 is the schematic diagram that describes the first defect measurement unit 112a of FIG. 2.

In the first defect measurement unit 112a, a predetermined solution X liquid is mixed with the resist mixture acquired from the acquisition port α and the acquisition port R. This dissolves the cluster defects E in the resist mixture. Then, the defects of the mixture mixed with the predetermined solution X is measured by FPT method.

The flow rate of the resist mixture acquired from the acquisition port α is measured by the flow meter 301. The flow rate of the resist mixture acquired from the acquisition port β is measured by the flow meter 302.

The predetermined solution X is stored in the solution storage tank 306 of the solution purification and circulation unit (solution purificator and circulator) 305. The predetermined solution X is filtered by the solution purification filter 308. The predetermined solution X is circulated by the solution circulation pump 307. In this way, the predetermined solution X is stored in the solution purification and circulation unit 305 while being filtered by the solution purification filter 308 in order to reduce the defects of the predetermined solution X as much as possible. Note that, for example, the defects of the predetermined solution X can be measured in advance using the first defect measuring instrument (first defect measurer) 317.

The predetermined solution X is not particularly limited, and for example, at least one solvent selected from the group consisting of aprotic polar solvent containing tetrahydrofuran (THF), N-methyl-2-pyrrolidone (NMP), N,N-dimethylformamide (DMF), methyl ethyl ketone (MEK), and propylene glycol dimethyl ether (PGME), protic polar solvent, toluene, and ethyl acetate, can be preferably used. For example, the same organic solvent as the organic solvent stored in the container 101 included in the resist mixture may be used as the predetermined the solution X.

The predetermined solution X passes through the valve 309a and is mixed with the resist mixture acquired from the acquisition port α by the first mixer 311 after the flow rate is measured by the flow meter 303. As a result, the first mixture is obtained. The first mixture passes through the valve 309c and is then sent to the first defect measuring instrument 317. Here, the first defects of the first mixture are measured using the defect detecting cell 314. The first mixture at which the first defects are measured is recovered at the drain 316.

If the flow rate of the first measurement object (first mixture) becomes too large, it may be difficult to perform the measurement of the defects by the defect detecting cell 314. Therefore, the flow rate of the first measurement object is controlled by the defect measurement cell flow rate regulator 315 provided between the defect detecting cell 314 and the drain 316. If the flow rate of the first measurement object becomes too high, the first mixture may be sent from the valve 309c to the drain 316 without passing through the defect detecting cell 314 and the defect measurement cell flow regulator 315, for example, via the bypass flow meter 313.

Further, the predetermined solution X passes through the valve 309b and is mixed with the resist mixture acquired from the acquisition port β by the second mixer 312 after the flow rate is measured by the flow meter 304. As a result, the second mixture is obtained. The second mixture passes through the valve 309c and is then sent to the first defect measuring instrument 317. Here, the second defects of the second mixture are measured using the defect detecting cell 314. The second mixture at which the second liquid defects are measured is recovered at the drain 316.

If the flow rate of the second measurement object (second mixture) becomes too large, it may be difficult to perform the measurement of the defects by the defect detecting cell 314. Therefore, the flow rate of the second measurement object is controlled by the defect measurement cell flow rate regulator 315 provided between the defect detecting cell 314 and the drain 316. If the flow rate of the second measurement object becomes too high, the second mixture may be sent from the valve 309c to the drain 316 without passing through the defect detecting cell 314 and the defect measurement cell flow rate regulator 315, for example, via the bypass flow meter 313.

The reason why the flow rate of the resist mixture acquired from the acquisition port α is measured by the flow meter 301 and the flow rate of the predetermined solution X is measured by the flow meter 303 is to strictly measure the amount of the defect in the first mixture by strictly controlling the amount of the predetermined solution X mixed with the first mixture.

The reason why the flow rate of the resist mixture acquired from the acquisition port β is measured by the flow meter 302 and the flow rate of the predetermined solution X is measured by the flow meter 304 is to strictly measure the amount of the defect in the second mixture by strictly controlling the amount of the predetermined solution X mixed with the second mixture.

The static mixer is preferably used as the first mixer 311 and the second mixer 312 used for mixing the resist mixture and the predetermined solution. The static mixer is a stationary mixer without a driver. For example, the first mixer 311 includes a pipe 311a, a plurality of right-handed spiral elements 311b and left-handed spiral elements 311c which are alternately arranged along the extending direction of the pipe 311a. The resist mixture obtained from the acquisition port α and the predetermined solution X passed through the valve 309a are mixed by passing through the first mixer 311. Similarly, the second mixer 312 includes a pipe 312a, a plurality of right-handed spiral elements 312b and left-handed spiral elements 312c which are alternately arranged along the extending direction of the pipe 312a. The resist mixture obtained from the acquisition port β and the predetermined solution X passed through the valve 309b are mixed by passing through the second mixer 312. By not having the driver, it is possible to suppress the defects from being increased when the resist mixture and the predetermined solution X are mixed. As the first mixer 311 and the second mixer 312, other mixers may be used.

It is preferable to appropriately determine the amount of mixing of the predetermined solution X and the configuration of the static mixer based on the time which is possible to dissolve (re-decompose) the cluster defect E, the amount of the predetermined solution X added, the flow rate of the resist mixture, and the like.

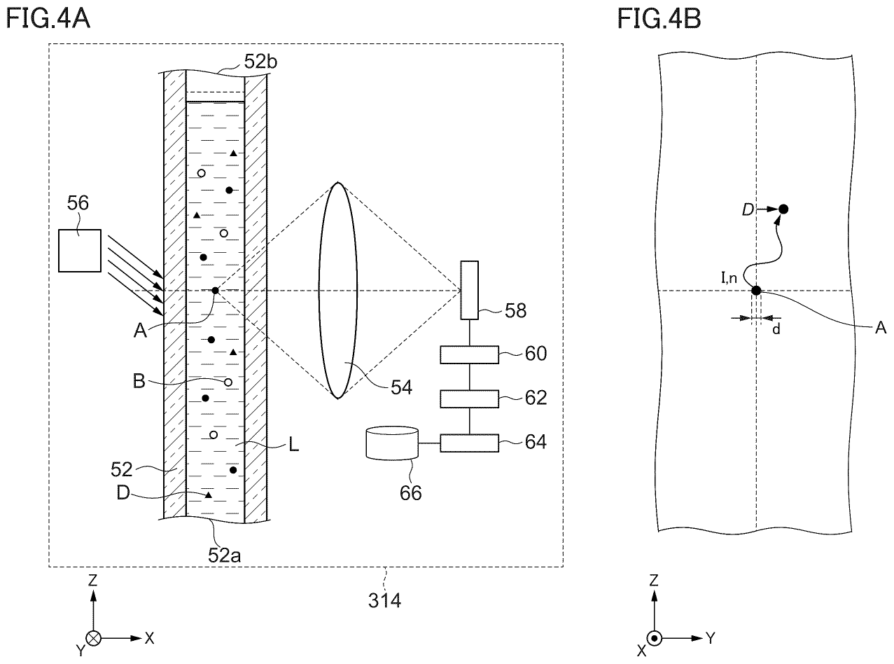

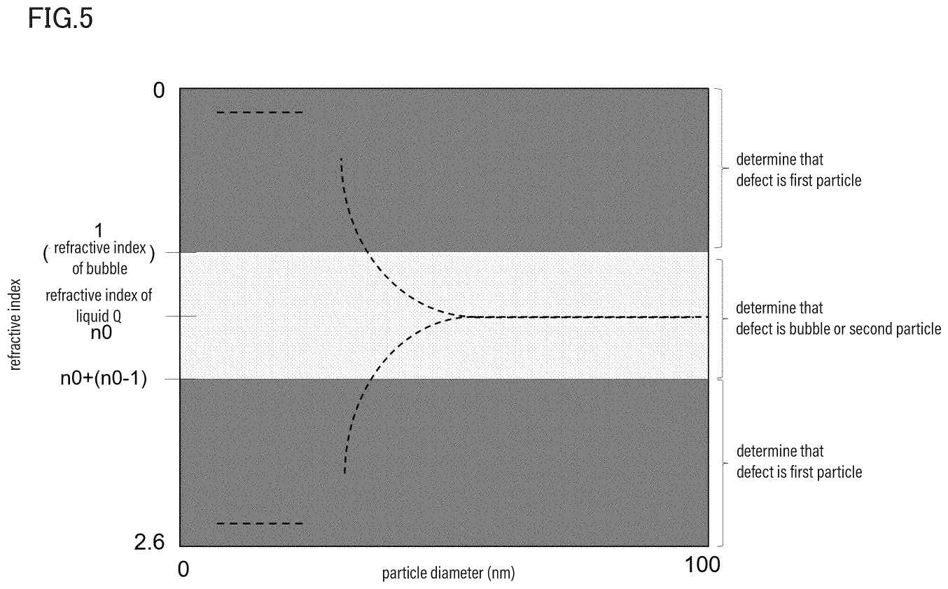

FIGS. 4 A-B are schematic diagrams of the defect detecting cell (evaluator) of the embodiment.

The defect detecting cell 314 acquires the particle size (geometric diameter) of the defect by FPT (Flow Particle Tracking method).

FIG. 4 A is the schematic diagram of the defect detecting cell 314 of the embodiment.

Here, an X-axis, a Y-axis intersecting perpendicularly to the X-axis, and a Z-axis intersecting perpendicularly to the X-axis and the Y-axis are defined. The Z-axis is opposite to the vertical direction.

The column 52 is a container that is transparent and capable of containing the first mixture or the second mixture. The flow of the first mixture or the second mixture in the column 52 is a laminar flow flowing along the Z-axis. The column 52 is formed of, for example, synthetic quartz or sapphire. For example, a valve 309c is connected to the column inlet 52a of the column 52. A defect measurement cell flow regulator 315 is connected to the column outlet 52b of the column 52.

The irradiation unit (irradiator, light source) 56 irradiates the irradiation light such as a laser with respect to the first mixture or the second mixture in the column 52. For example, when the first mixture or the second mixture in the column 52 flows in the Z-axis direction, the irradiator 56 irradiates the liquid Q with the irradiation light in the X-axis direction with respect to the first mixture or the second mixture. Note that the irradiation direction of the irradiation light is not limited to the X-axis direction.

The imaging unit (imager) 58 includes a CCD (Charge Coupled Device) sensor, a CMOS(Complementary Metal Oxide Semiconductor) sensor, or the like. The imaging unit 58 uses the lens 54 or the like to image the first mixture or the second mixture in the column 52. Then, moving images of the scattered light emitted from the defects are acquired. FIG. 4B is an example of the schematic diagram of the moving images of the metal particle A acquired by the imaging unit 58. The analyzing unit (analyzer) 60 obtains the diffusion coefficient D of the bubble B, the metal particle A, and the particle D that differ from the bubble B and the metal particle from the moving image. Here, the metal particle A is an example of the first particle. In addition, the particle D is an example of the second particle.

When the defect performs Brownian motion in the first mixture or the second mixture, the moving image of the scattered light of the defects can be used to determine the diffusion coefficient D of the defects. The particle size d of the defects and the diffusion coefficient D are connected by the relations below.

$$\begin{matrix}[ Mathematical formula 1 ] & \\ D = \frac{{k}_{B} T}{3 πη d} & ( 1 )\end{matrix}$$

In Equation (1), D is the diffusion coefficient of the defect, k_{B} is Boltzmann's constant, T is the absolute temperature, η is the viscosity (viscosity factor) of the first mixture or the second mixture, and d is the particle size of the defect. The calculating unit (calculator) 62 can determine the particle size d of the defect from the diffusion coefficient D using Equation (1).

In addition, the refractive index of the defect can be obtained from the following equation.

$$\begin{matrix}[ Mathematical formula 2 ] & \\ I ∝ {I}_{0} \frac{c}{2 {r}^{2}} {( \frac{2 π}{λ} )}^{4} {( \frac{d}{2} )}^{6} {\vert \frac{{m}^{2} - 1}{{m}^{2} + 2} \vert}^{2} & ( 2 )\end{matrix}$$

In Equation (2), I is the intensity of the scattered light, I₀ is the intensity of the incident light, c is the number concentration of the defects, r is the distance from the defect to the imaging unit 58, λ is the wavelength of the incident light, d is the particle size of the defect, and m is the relative refractive index of the defect to the first mixture or the second mixture. The relative refractive index m is the refractive index n of the defect divided by the refractive index n0 of the first mixture or the second mixture (m=n/n0). If the refractive index n0 of the first mixture or the second mixture is known, the calculating unit 62 can determine the refractive index n of the defect using Equation (2).

The determination unit (determinator) 64 uses the refractive index n determined by the calculating unit 62 to determine whether the defect is the bubble or the metallic particle A, or the particle D. For example, the determination unit 64 is connected to the database 66 in which the refractive index of a known substance is stored. For example, the determination unit 64 refers to the refractive index of such known substance in the above decision.

FIG. 5 is an example of the evaluation of a liquid containing the defects using the evaluation unit (evaluator) 314 of the embodiment. The plot shown in FIG. 5 is the particle size d of the defect with the horizontal axis and the refractive index n of the defect calculated by the calculating unit 62 with the vertical axis.

FIG. 5 shows similar distributions at the top and the bottom, centered on the refractive index no of the first mixture or the second mixture. In other words, the calculating unit 62 provides two refractive indices n around the refractive index no of the first mixture or the second mixture for the same particle size d. This is because Equation (2) is a quadratic equation of the relative refractive index m. Therefore, by comparing the relative refractive index m obtained by Equation (2) with known refractive index data, the evaluation method of the embodiment becomes a semi-qualitative method.

Specifically, when the refractive index of the first mixture or the second mixture to be measured is taken as n0, it is preferable that the determination unit 64 determines that the defect is the metal particle when the refractive index n is larger than n0+(n0−1) or the refractive index n is smaller than 1. When the refractive index of the first mixture or the second mixture to be measured is taken as n0, it is preferable that the determination unit 64 determines that the defect is the bubble or the particle D when the refractive index n is 1 or more or n0+(n0−1) or less. In other words, centered on the refractive index n0 of the first mixture or the second mixture, when the refractive index n within the range of the difference between the refractive index n0 of the first mixture or the second mixture and the refractive index 1 of the bubble is calculated, it is determined that the defects contain the particle D or the bubble. Further, centered on the refractive index n0 of the first mixture or the second mixture, when the refractive index n out of the range of the difference between the refractive index n0 of the first mixture or the second mixture and the refractive index 1 of the bubble is calculated, it is determined that the defects contain the metal particle A. The refractive index n0 of the first mixture or the second mixture to be measured is, for example, 1.2 to 1.5, but is not limited thereto.

Note that the database 66 may not be provided. The determination unit 64 may distinguish the bubble from the metal particle by simply using the magnitude relation of the refractive index.

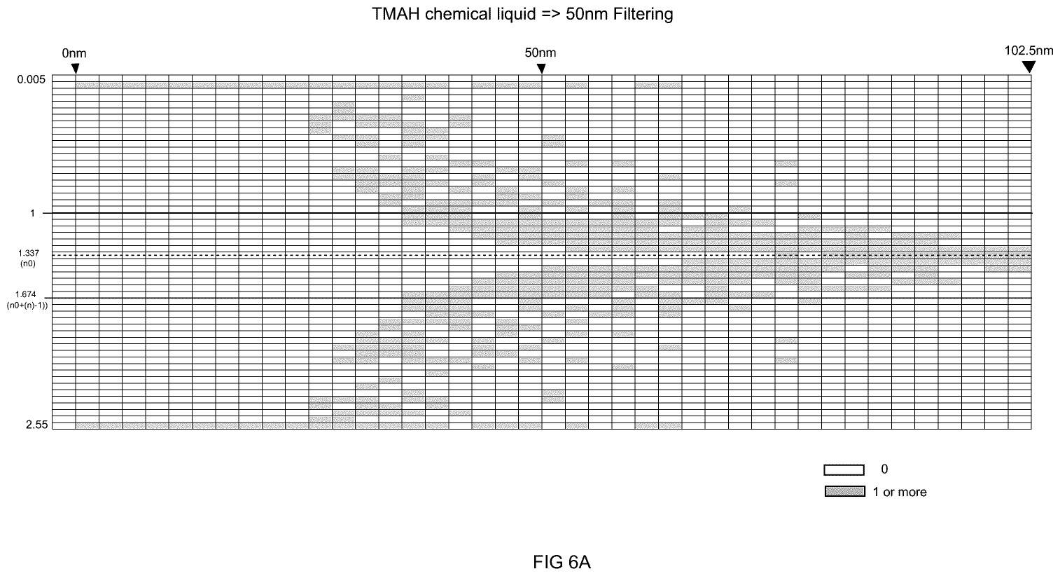

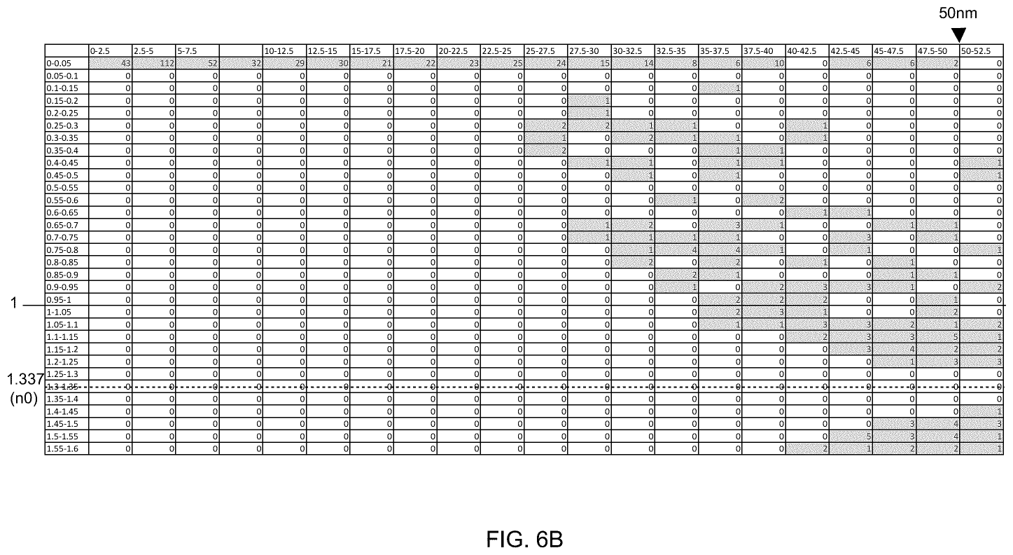

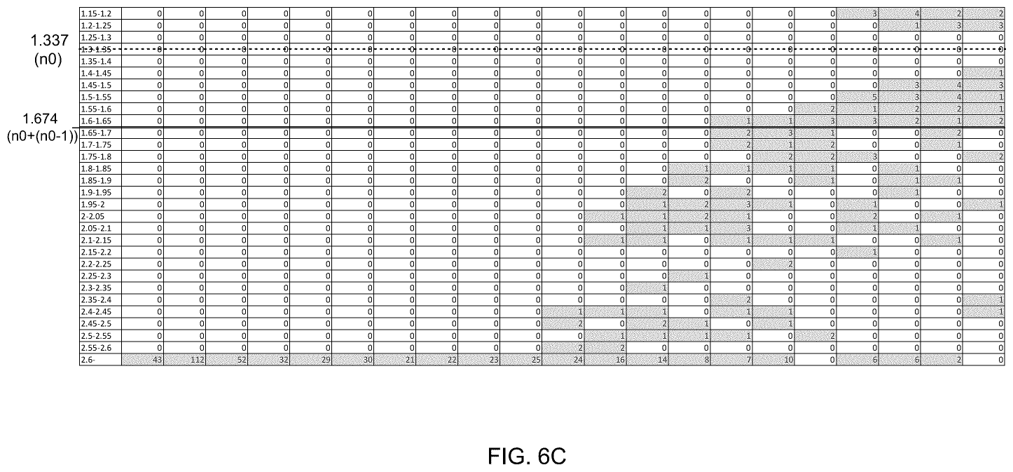

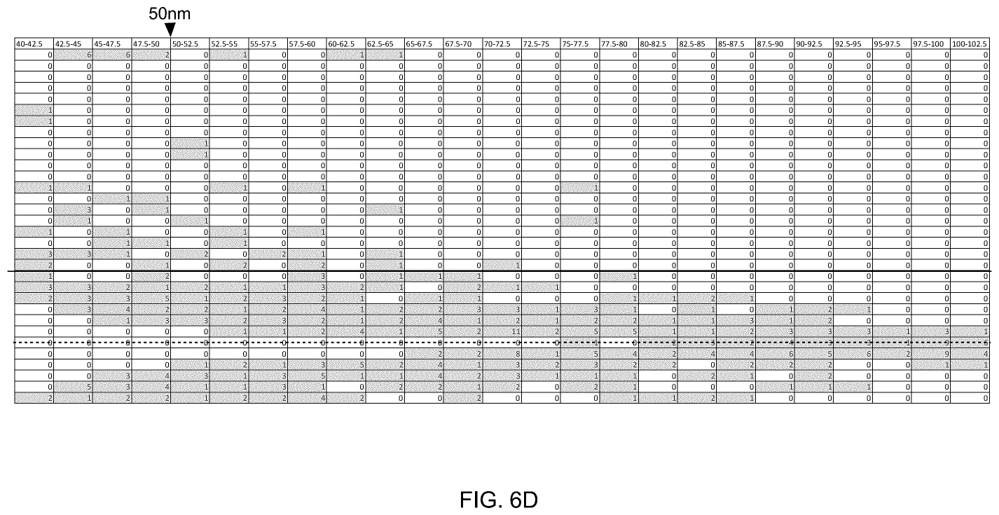

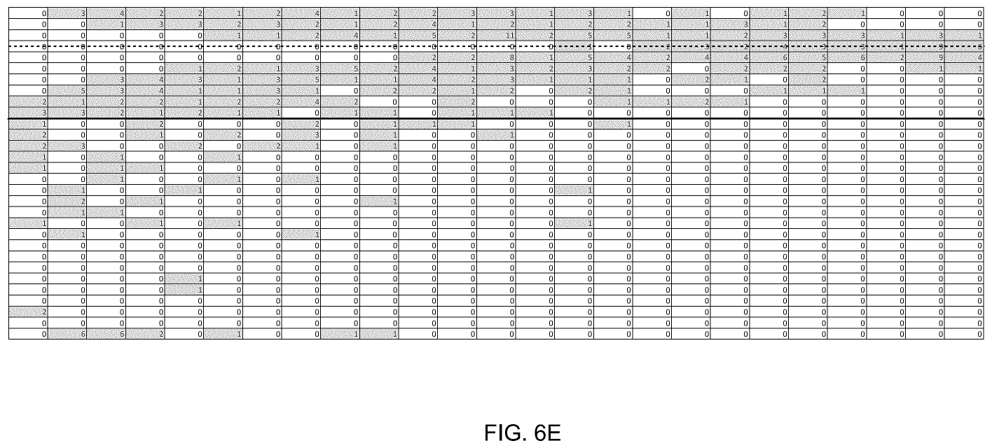

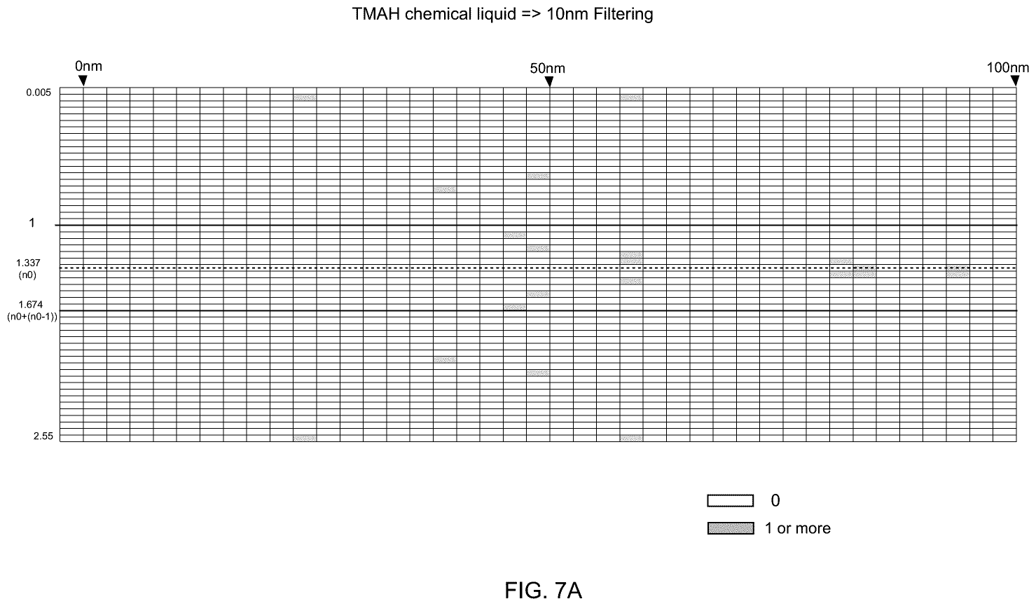

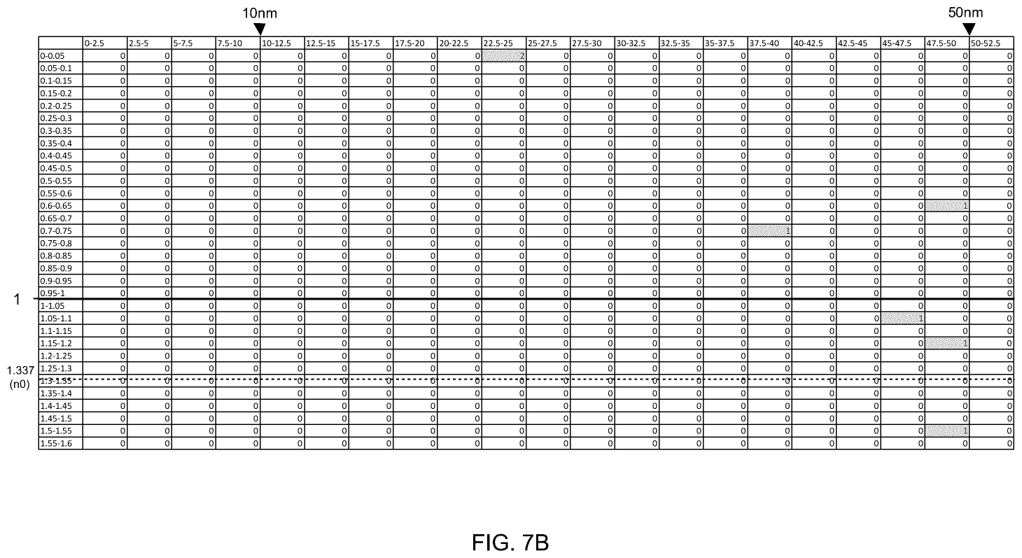

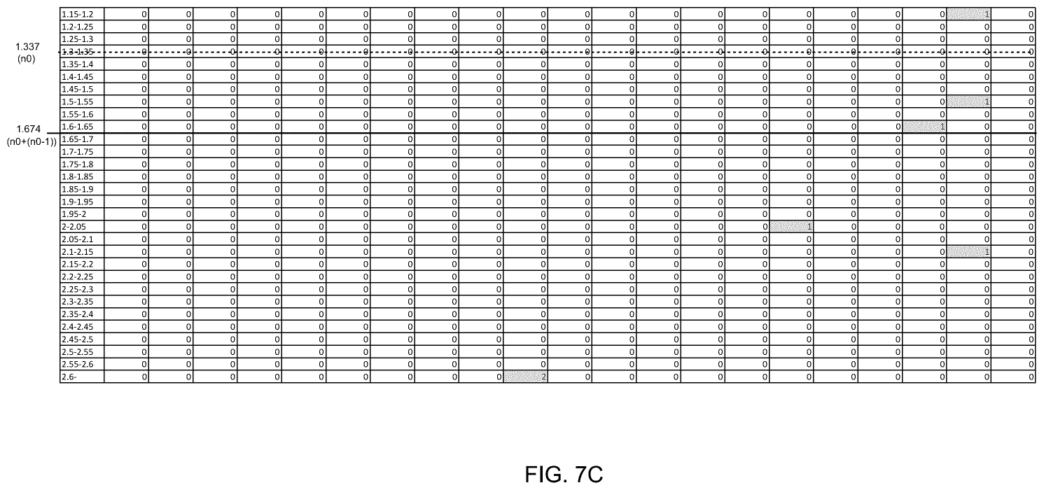

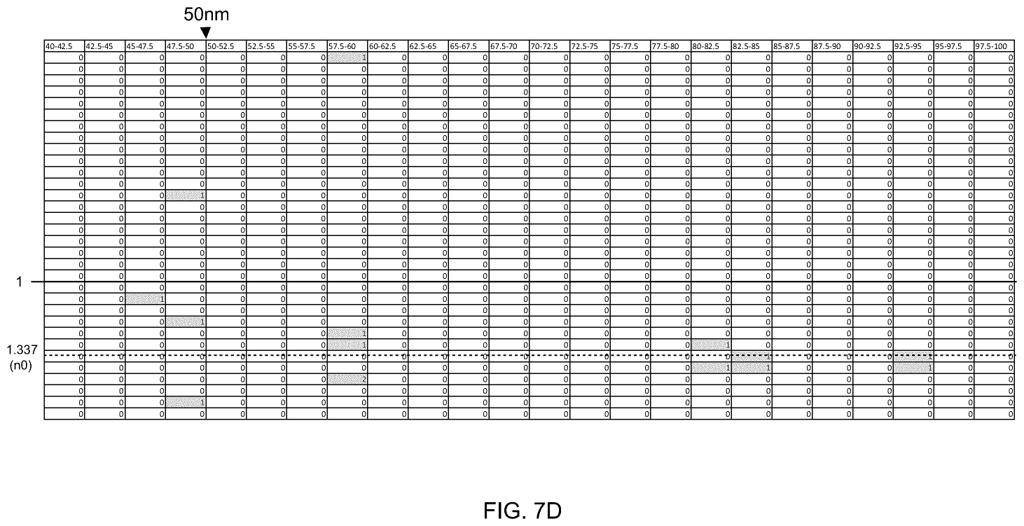

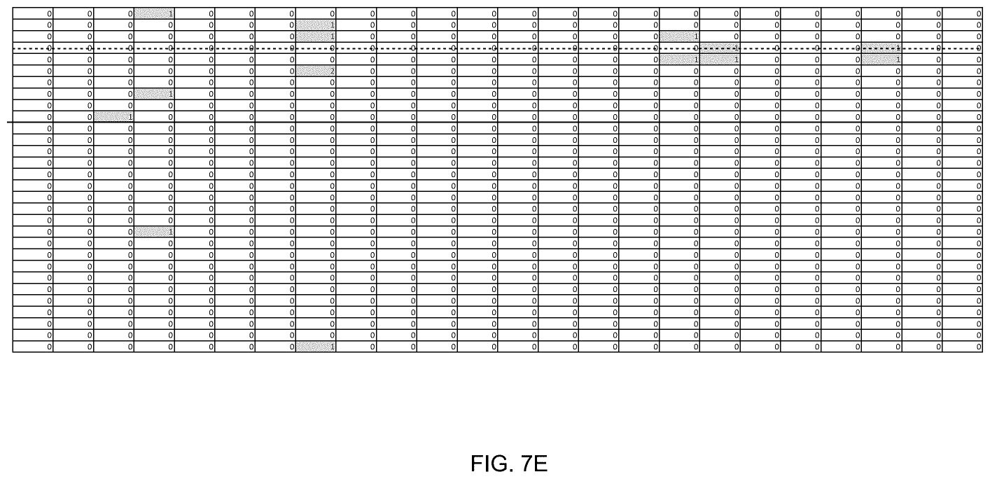

FIGS. 6 A-E and FIGS. 7 A-E are more specific examples of evaluating the liquid containing the defects.

When the sum of the number of defect detections in the range of the refractive index n>n0+(n0−1) is a(1) and the sum of the number of defect detections in the range of the refractive index n<1 is a(2), the number of the metal particles A in the liquid can be expressed by the following equation.

(a(1)+a(2))/2=number of the metal particles A (3)

When the sum of the measured values in the refractive index n of n0+(n0−1)≥n≥1 is represented by a(3), the number of the bubbles B or the particles D in the liquid can be expressed by the following equation.

a(3)/2=number of the bubbles B or the particles D (4)

Further, by applying a(1), a(2), and a(3) in a certain defect diameter d to the above equations, the number of the metal particles A, the bubbles B or the particles D in the defect diameter can also be obtained.

In both equations, the sum of the measurements in each defect species is divided by 2, because the refractive index n obtained from equation (2) has two solutions for each detected defect.

The defect diameter d determined by the calculating unit 62, and the distribution of the defects detected from the refractive index n are shown in FIGS. 6 A-E and FIGS. 7 A-E. FIGS. 6 A-E show the distribution of the defects in TMAH after passing through the filter of the pore size of 50 nm. FIGS. 7 A-E show the distribution of the defects in TMAH after passing through the filter of the pore size of 50 nm and further passing through the filter of the pore size of 10 nm. The horizontal axis indicates the defect diameter d, and the vertical axis indicates the refractive index n.

In FIGS. 6 A-E and FIGS. 7 A-E, the defect diameter d (horizontal axis) is divided into 2.5 nm in the range of 0 to 100 nm, and the refractive index n (vertical axis) is divided into 0.05 in the range of 0 to 2.6 to show the number of defect detections in each region. In the distribution diagram, the areas where one or more defects are detected are colored in the darkest color.

For example, consider determining the number of the metal particles A, or the bubbles B or the particles D from FIGS. 6 A-E and FIGS. 7 A-E. In this case, since the refractive index of TMAH is 1.337, the number of the metal particles A is the sum of the number of defect detections in the range of the refractive index n>1.674 and n<1 divided by 2. The number of the bubbles B or the number of particles D is the sum of the number of defect detections in the range of 1.674≥n≥1 divided by 2.

From FIGS. 6 A-E, in the case of the 50 nm filter, one or more defects are detected in an area where the defect diameter d is 30-50 nm. In particular, the number of defect detections is large in the range where the refractive index is n>1.674 and n<1. Therefore, it can be seen that many metal particles, the bubbles, or other particles are passing through. On the other hand, from FIGS. 7 A-E, in the case of the 10 nm filter, the number of defect detections is small in the range where the defect diameter d is 30-50 nm and the refractive index is n>1.674 and n<1. From this, it can be seen that the metal particles are decreasing. In this way, it can be seen that the evaluation method of the embodiment can more appropriately evaluate the filter elimination performance by FPT measurement in which the correct geometric diameter is obtained from the diffusion coefficient D.

The analyzing unit (analyzer) 60, the calculating unit (calculator) 62, and the determination unit (determinator) 64 are, for example, electronic circuits. The analyzing unit 60, the calculating unit 62, and the determination unit 64 are, for example, computers composed of a combination of hardware such as arithmetic circuits and software such as programs.

The database 66 is, for example, a storage device such as a semiconductor memory or a hard disk.

When the defects are detected based on the light scattering method, the bubble in the liquid is also detected as the defect. Therefore, it is not possible to evaluate the filter collection performance of the liquid containing a large amount of the bubble.

On the other hand, according to the FPT method, it is possible to determine whether the defect is the bubble or the particle D, or the metal particle A, by using the difference of the refractive index.

When the refractive index of the first mixture or the second mixture to be measured is n0, it is preferable to determine that the defects contain the metal particle M when the refractive index n is larger than n0+(n0−1) or the refractive index n is smaller than 1. Further, it is preferable to determine that the defects contain the bubble or the particle D when the refractive index n is 1 or more or the refractive index n is n0+(n0−1) or less.

The refractive index of the particle containing metal is larger than 2.0 or less than 0.5. For example, the refractive index of silver is 0.17. Further, the refractive index of gold is 0.34. Further, the refractive index of iron hydroxide oxide is 2.00. Further, the refractive index of chromium oxide (trivalent) is 2.50. Therefore, the defect having the refractive index larger than 2 or less than 0.5 may be determined as the metal particle.

Further, the refractive index of nitrogen (the bubble) is 1. Further, the refractive index of ultrapure water is 1.33. Further, the refractive index of fluoropolymer is 1.35. The refractive index of silica (quartz) is 1.45. The refractive index of polystyrene latex (PSL) is 1.59. Therefore, it may be determined that the defect having the refractive index of 0.5 or more and 2 or less is the bubble or the particle D.

The pore size of the filter 80b is preferably 100 nm or less. The defect having the particle size larger than 100 nm does not perform Brownian motion. Therefore, it is difficult to obtain the particle size d.

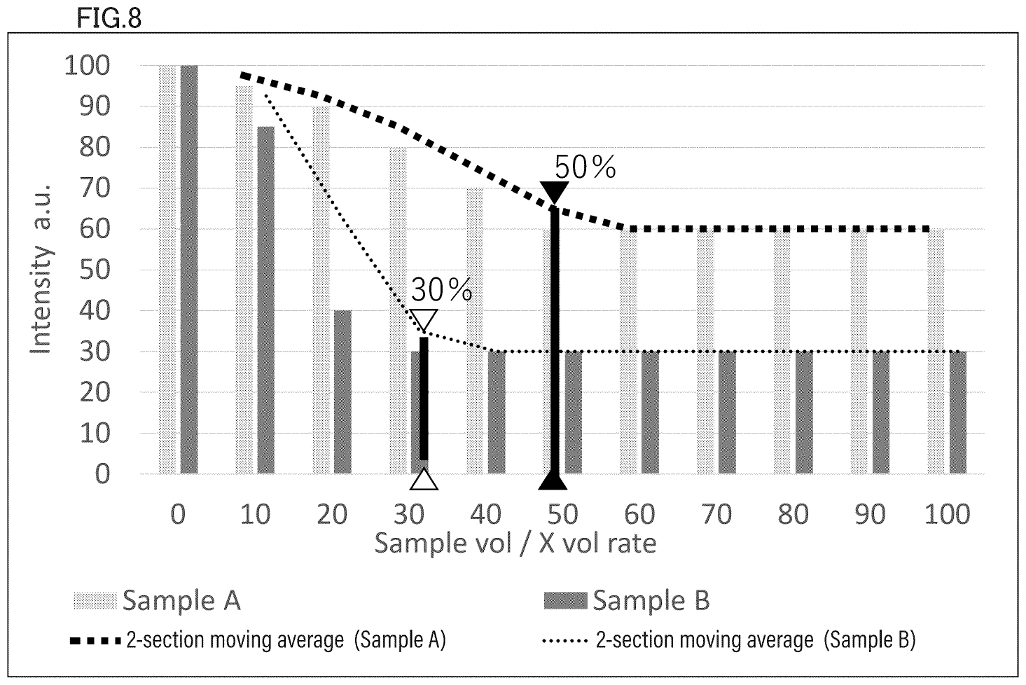

In FIG. 8, a conceptual diagram of the light scattered background I which changes according to X ratio added to the resist SampleA and SampleB, i.e. composed of two different high polymer resins.

In SampleA, when the background scattered light strength was reduced and saturated, the ratio of X added to dissolve the cluster defects E in which the organic components and the impurities were aggregated was about 50% by volume. From this result, X was mixed at a volume density of 50% to measure the defects of SampleA.

In SampleB, when the background scattered light strength was reduced and saturated, the ratio of X added to dissolve the cluster defects E in which the organic components and the impurities were aggregated was about 30% by volume. From this result, X was mixed at a volume density of 30% to measure the defects of SampleB.

As described above, by adding an appropriate amount of a clean solvent capable of dissolving the cluster defect E, the background scattered light strength caused by the cluster defect E can be reduced even in the case of the resist liquid. As a result, it is possible to accurately measure the defects during the mixture filtration other than the high polymer resin, and the defect presence status in the resist mixture acquired from the acquisition port α before passing through the filter 106, acquired from the acquisition port β after passing through the filter 106.

Next, an embodiment of the method of manufacturing the resist and to measure the defects during the resist mixture filtration will be described.

### EXAMPLES

Examples 1 to 3 will be described below.

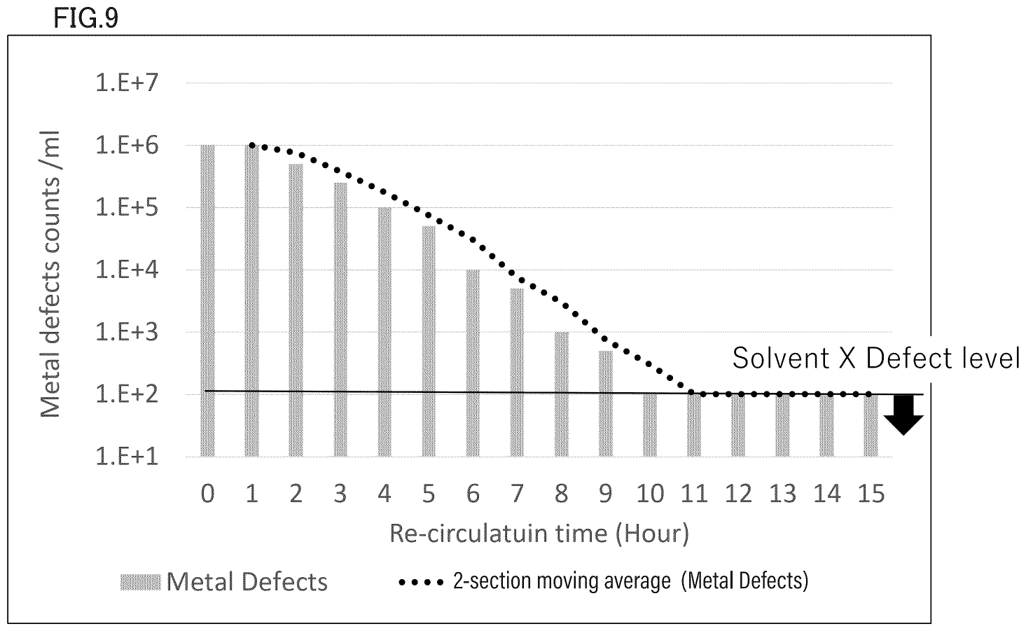

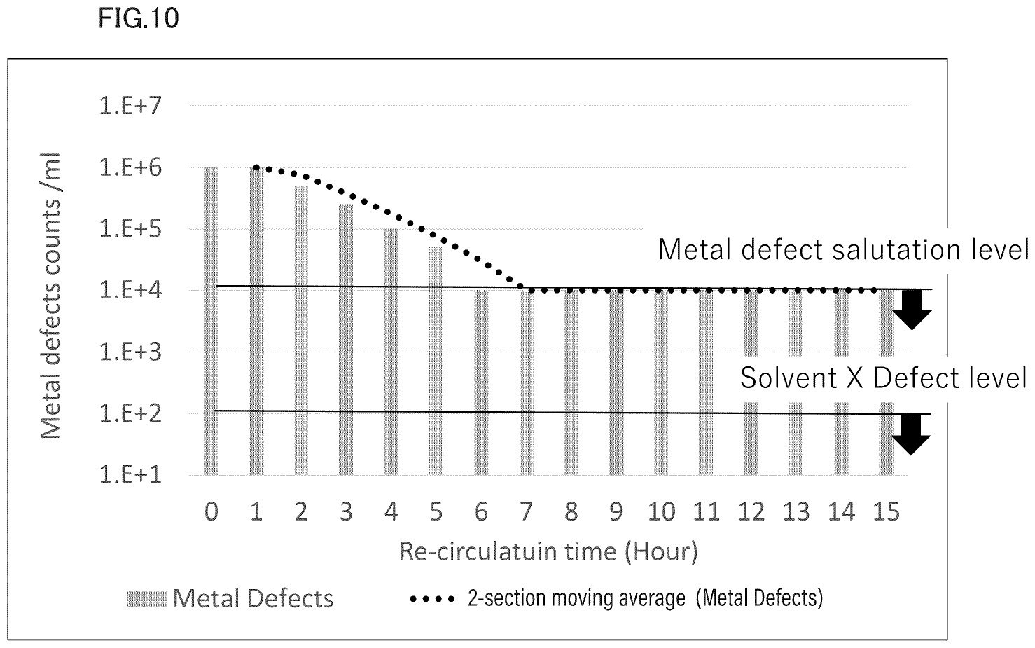

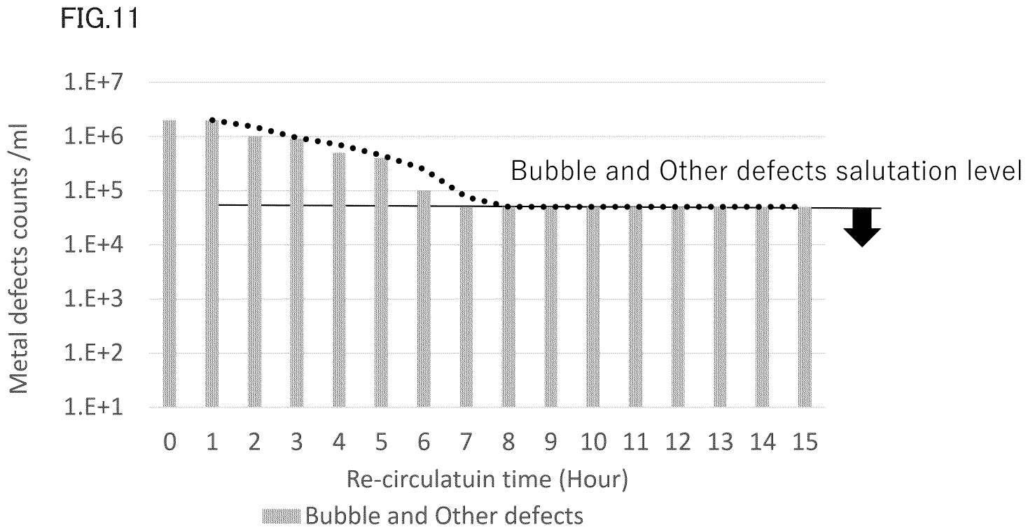

The resist mixture containing the organic solvent, the high polymer resin, the photosensitizer, and the additive as main components is stored in the mixing vessel 100. The resist mixture is then agitated and mixed using the mixer 104 placed in the mixing vessel 100. Next, the fluid aspiration discharge pump 105 is operated. The “defects during the resist mixture filtration” of the resist mixture obtained at the acquisition port β is shown in FIG. 9, FIG. 10, and FIG. 11 as examples of the change with time of circulation filtration of the total amount of the metal particles A measured by FPT method.

### Example 1

As shown in FIG. 9, this example illustrates the case where the total amount of the metal particles A in the resist mixture measured by FPT method is simply reduced over time.

“The metal particles A outputted in RI (the refractive index) measuring mode of FPT” monotonically decreases with the elapsed time of the filtration (time for circulating the resist mixture in the path in which the filter 106 is included in the resist manufacturing device 500). The number of defects having a geometric diameter of 12 nmφ or more in DC measuring mode, which is the detection limit in FPT method, is reduced to 100/ml or less.

This defect count is the defect level in the organic solvent X (predetermined solution X) used for the dissolution of the cluster defect E. Therefore, it can be seen that cleaning of the organic solvent X (predetermined solution X) is required in order to reduce the number of defects.

As described above, in the method of manufacturing the resist, the number of defects is reduced to the limit or less of the detection limit of FPT method, so that the circulation filtration of the resist mixture can be completed. Therefore, the process can be transferred to the subsequent process, i.e., the resist shipping process and the resist bottle filling (the container filling) process.

Also, in filling the resist into the resist shipping bottle in the next process, the B liquid (the resist mixture) obtained at the acquisition port β can be monitored at each stage of the resist bottle filling stage in the early stage, the middle stage, and the late stage. As a result, it is possible to confirm the presence or absence of a change in the metal particles A while the entire resist solution in the resist mixing vessel is bottled (for example, for about 12 hours). Thus, the resist quality assurance can be performed at the same time.

It is considered that the total amount of the metal particles A in the resist mixture measured by FPT method does not monotonically decrease with the passage of the filtration, and a disturbance occurs in the behavior. In this situation, the resist mixture α solution from the acquisition port α (defect measurement sampling point α) before passing through the filter 106 (primary side) is also measured by FPT method after confirming the situation for a certain period of time and confirming that the situation does not change, and the number of the defects is determined. It can be determined that the filter 106 does not exhibit the particle-removing performance if it is found that the number of defects obtained by measuring the resist mixture β solution obtained from the acquisition port β after passing through the filter 106 (secondary side) by FPT method and the number of defects obtained by measuring the resist mixture α solution obtained from the acquisition port α before passing through the filter 106 (primary side) by FPT method is the same. For example, it can be determined that a breakthrough trouble has occurred in the filter 106. Therefore, the circulation filtration can be stopped immediately, and the filter replacement can be performed.

### Example 2

As shown in FIG. 10, this example shows a case in which the total amount of the metal particles A in the resist mixture measured by FPT method monotonically decreased until the middle of the state elapsed time, and however, the defects reduction becomes saturated in the middle of the filtration.

In the case shown in FIG. 10, the total amount of metal particles A in the resist mixture measured by FPT method monotonically decreased with the passage of time. However, the total amount of metal particles A in the resist mixture did not decrease to the limit of detection by FPT method shown in FIG. 9 (DC (diffusion equivalent diameter) measurement mode, geometric diameter of 12 nmφ or more, and 100/ml or less), but was saturated with 10000/ml. That is, the saturation level of FPT measurement result in the example shown in FIG. 10 was higher than the saturation level of FPT measurement result in the example shown in FIG. 9.

FIG. 11 shows the change in the filtration elapsed time of “the total number of defects including the bubbles B+and other defects D outputted in RI (the refractive index) measuring mode of FPT”.

For example, as shown in FIG. 10, when the total amount of the metal particles A in the resist mixture measured by FPT method does not decrease and the number of metal particles A decreases to the state whose defects are larger than the desired state (100 pieces/ml or less) and the reduction is saturated, as shown in FIG. 11, “the bubbles B outputted in FPT (the refractive index) measuring mode+the number of defects combined with the defects D” should be checked for the change in the elapsed filtration time. When FPT measurement and RI (the refractive index) measurement of FPT behave in the same way, it is possible to confirm that the co-entrainment of the metal particles A due to the presence of the bubbles B is occurring.

Here, it is generally difficult to suppress the co-entrainment phenomena of the metal particles A caused by the bubble B by the filter. Therefore, it can be determined that there is no meaning of defect reduction even if further circulation filtration purification is performed. Therefore, the fluid aspiration discharge pump 105 is stopped.

When the filter is obtained, which is effective in suppressing the co-occurrence of the metal particles A due to the bubble B, it is thought that the number of defects can be reduced by circulation filtration even in resists in which the bubbles are easily contained in the foaming liquid.

As described above, by using the embodiment in the method of manufacturing the resist, it is possible to accurately evaluate the amount of defects in the resist mixture after the circulation filtration purification. As a result, it is possible to correctly confirm the quality in the resist circulation purification step, and it is possible to transfer to the filling step to the resist bottle, which is the next step.

### Example 4

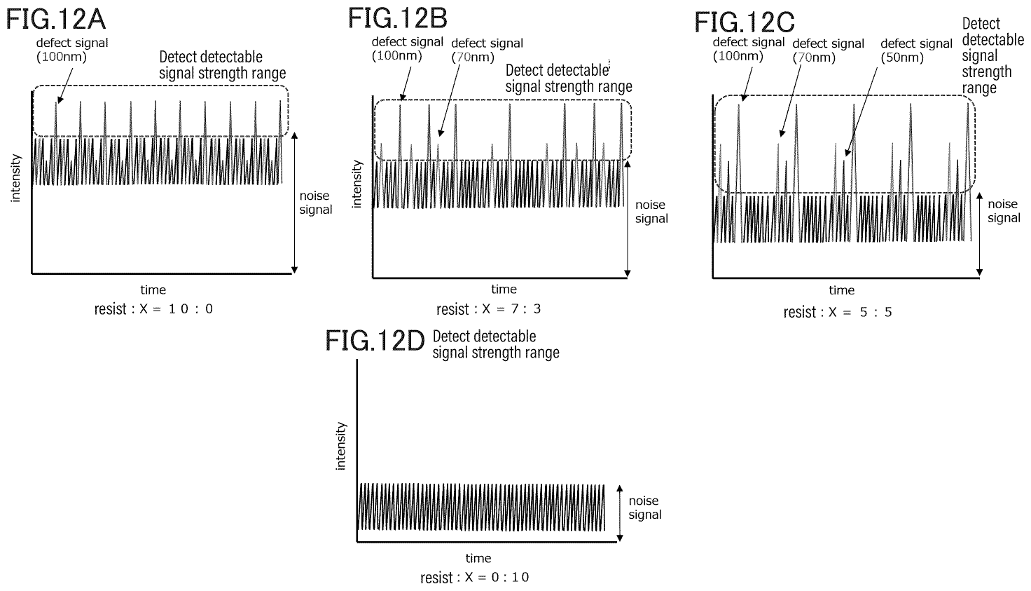

FIGS. 12 A-D shows the mix-ratio dependence of the resist mixture and the predetermined solution X as measured by FPT method.

If the predetermined solution X is not mixed, the strength of the noise signal due to cluster defects E is very high, as shown in FIG. 12A. Therefore, only relatively large defects with the particle size of a 100 nm degree can be detected.

FIG. 12B is the defect measured by FPT method when the mixing ratio of the resist mixture and the predetermined solution X is 7:3. FIG. 12C is the defect measured by FPT method when the mixing ratio of the resist mixture and the predetermined solution X is 5:5.

On the other hand, as shown in FIG. 12B and FIG. 12C, when the mixing ratio of the predetermined solution X is increased, the number of signals detected from the defect having 100 nm degree of the particle size decreases. This is because the number of defects in the solutions decreases as the mixing ratio of the predetermined solution X increases.

On the other hand, in FIG. 12B, the particle size can be measured from the defect having a 70 nm degree. In FIG. 12C, the particle size can be measured from a 50 nm level of the defect. This is because, when the predetermined solution X is mixed, the strength of the noise signal caused by the cluster defect E is reduced because the cluster defect E is dissolved. In other words, the resist mixture itself is not measured by FPT method, but is measured by mixing the resist mixture and the predetermined solution X to increase the signal-measurable range in accordance with the mixing ratio. As a result, the defects in the resist solution can be appropriately controlled in the circulation filtration purification method of manufacturing the resist of the embodiment

FIG. 12D is the defect measurement using FPT method for the predetermined solution X.

### Second Embodiment

The method of manufacturing resist of the present embodiment is different from the method of manufacturing the resist of the first embodiment in that the measuring the first defects further includes measuring the first defects of the first mixture irradiated with the first irradiation light using SP-ICP-MS method.

The method of manufacturing resist of the present embodiment is different from the method manufacturing resist of the first embodiment in that the first defects of the first mixture are measured using SP-ICP-MS method.

Descriptions of the contents overlapping with those of the first embodiment will be omitted.

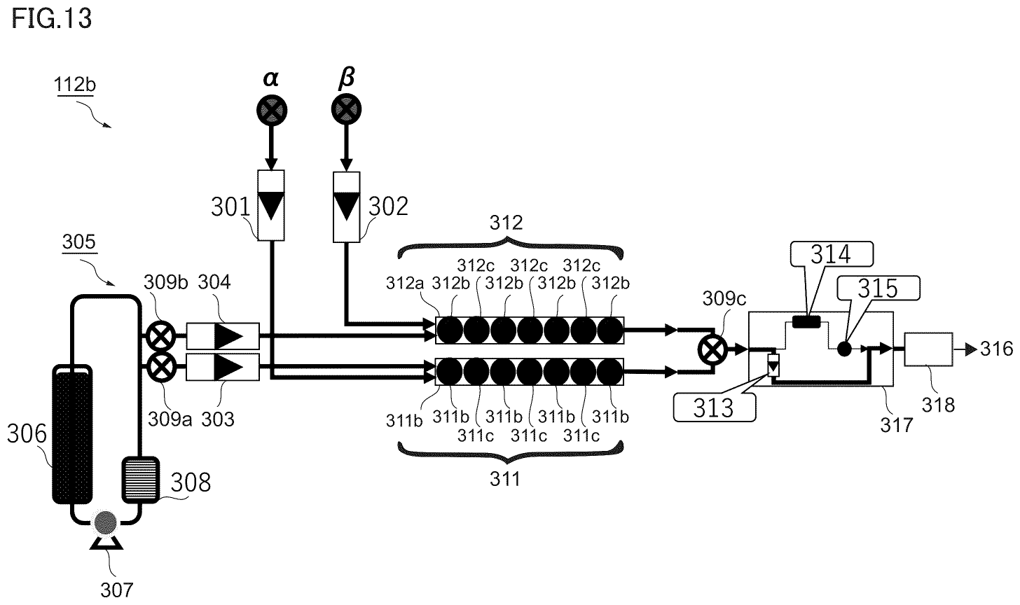

FIG. 13 is the schematic diagram explaining how to measure the defects in the resist solution of the present embodiment. FIG. 13 is the schematic diagram for describing the first defect measurement unit 112b of the present embodiment.

After the first defects of the first mixture are measured using the defect detecting cell 314 of the first defect measuring instrument 317, the first mixture is sent to the second defect measuring instrument 318 prior to being collected at the drain 316. Then, the first defects of the first mixture are measured using the second defect measuring instrument 318. The second defect measuring instrument 318 measures the first defects of the first mixture by the SP-ICP-MS (Single-Particle ICP (Inductively Coupled Plasma)-MS (Mass Spectrometry)) method. By using the SP-ICP-MS method, the data of the elements of the metal particles A detected by the first defect measuring instrument 317 can be obtained.

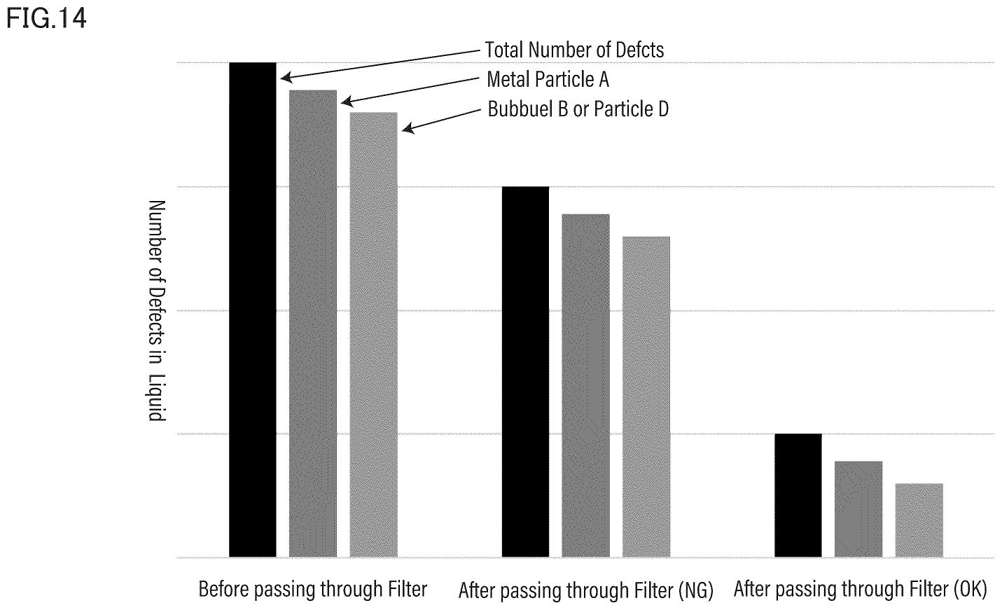

FIG. 14 is an example of evaluating the liquid including the defects performed using the defect detecting cell 314 of the present embodiment. By passing through the filter 106, the total number of defects, the number of metal particles A, the number of the bubbles B or the number of particles D are reduced. For example, the container 111 can be filled when the total number of defects, the number of metal particles A, the number of the bubbles B, or the number of particles D becomes equal to or less than a predetermined threshold.

FIG. 15 is an example of evaluating the liquid including the defects performed using the second defect measuring instrument 318 of the present embodiment. When the measurement is performed using the SP-ICP-MS method, time changes in strength for certain types of atomic species (e.g., Fe, etc.) are obtained. For example, if the first defects of the first mixture prior to passing through the filter 106 is measured, a high-intensity SP-ICP-MS method signal is frequently observed. By passing through the filter 106, the signal strength observed by the SP-ICP-MS method is decreased. In addition, by passing through the filter 106, the frequency of the signal by the SP-ICP-MS method is decreased. Then, for example, the frequency and strength of the signal by the SP-ICP-MS method are taken into account to determine whether the container 111 can be filled.

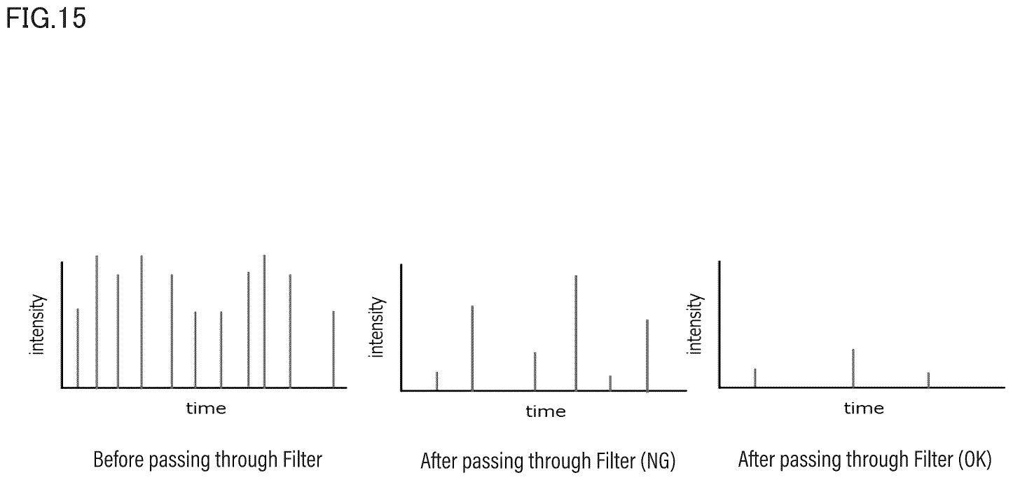

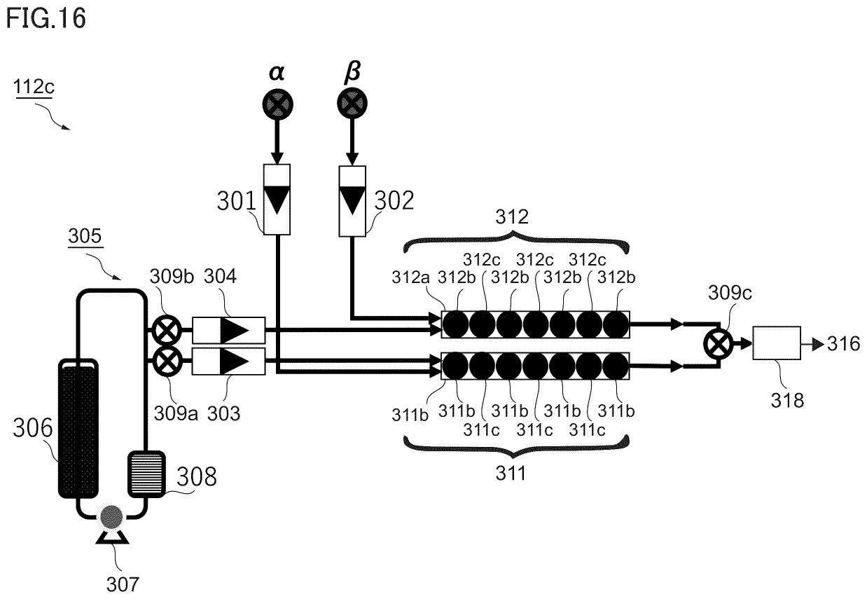

FIG. 16 is the schematic diagram explaining how to measure the defect in the resist solution according to another aspect of the present embodiment. In the first defect measurement unit 112c of FIG. 16, the first defects of the first mixture are measured using the second defect measuring instrument 318. The defect detecting cell 314 of the first defect measuring instrument 317 is not used.

By using the present embodiment in the method of manufacturing the resist, it is possible to accurately evaluate the number of defects in the resist mixture after the circulation filtration purification. As a result, it is possible to correctly confirm the quality in the resist circulation purification step.

### Third Embodiment

The method of manufacturing the resist of the present embodiment is different from those of the first and second embodiments in that the method further includes obtaining a third mixture by mixing the filtered resist mixture and a predetermined second solution; measuring third defects of the third mixture; obtaining a fourth mixture by mixing the filled resist mixture and the predetermined second solution; measuring fourth defects of the fourth mixture; and comparing the third defects and the fourth defects.

Further, the method of manufacturing the resist of the present embodiment is different from those of the first and second embodiments in that comparing the third defects and the fourth defects includes when a difference obtained by subtracting the number of the third defects from the number of the fourth defects is larger than a second predetermined first value, delivering the filled resist mixture to the mixing vessel.

Here, a description that overlaps with the resist manufacturing method of the first and second embodiments will be omitted.

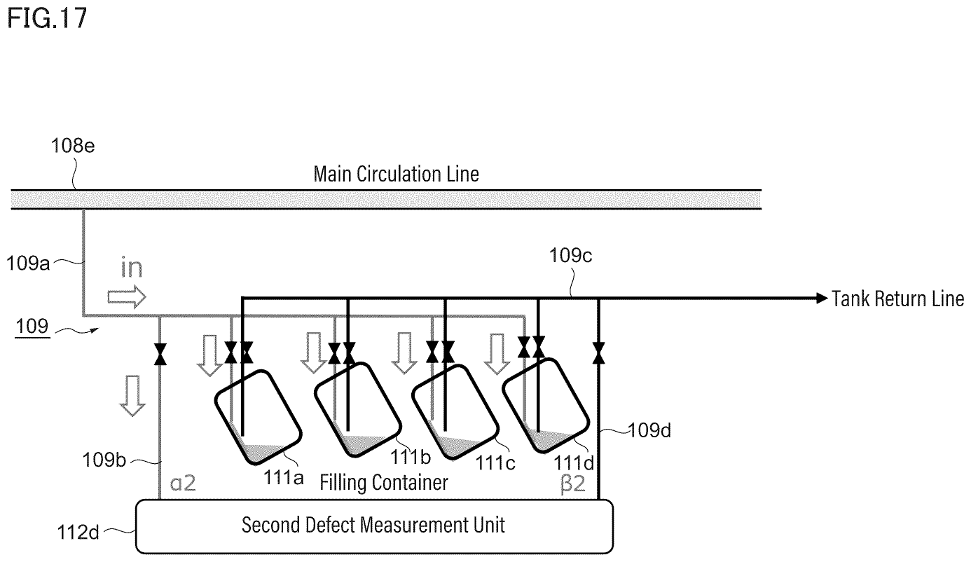

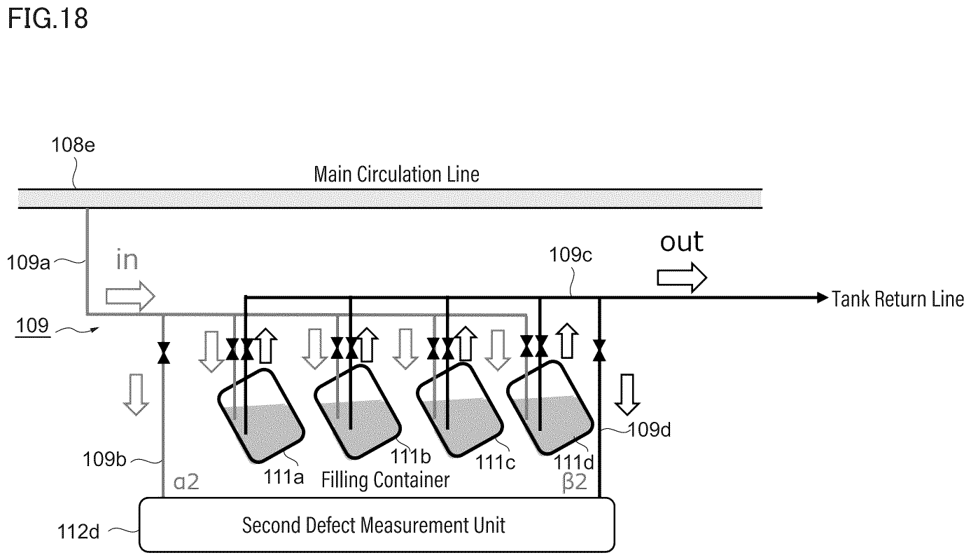

FIG. 17 and FIG. 18 are the schematic diagrams of a method of manufacturing the resist according to the present embodiment.

Filling the resist bottle, i.e. the container, with the resist mixture with the low-defect content in the resist mixture is of great importance in the method of manufacturing resist. FIG. 17 and FIG. 18 are the schematic diagrams for the filling portion 109 (FIG. 2) and the container 111 (FIG. 2) to fill the resist.

The resist bottles, i.e. the containers 11a, 1l1b, 1l1c and 111d, are filled with the filtered resist mixture using the pipe 109a connected to the pipe 108e. Here, although the number of containers is four, the number of containers is not limited to four.

Here, the resist mixture before filling into the containers 111a, 111b, 111c, and 111d is introduced into the second defect measurement unit 112d through the acquiring port α2 using the pipe 109b (FIG. 17, FIG. 18). The resist mixture after filling into the container 111a, 111b, 111c and 111d is introduced into the second defect measurement unit 112d from the acquiring port β2 using the pipe 109d (FIG. 18). Then, with respect to the resist mixture acquired from the acquisition port α2 and the resist mixture acquired from the acquisition port β2, the type and the number of defects are measured using the second defect measurement unit 112d. Then, the third defects of the resist mixture acquired from the acquisition port α2 and the fourth defects of the resist mixture acquired from the acquisition port β2 are compared.

The configuration of the second defect measurement unit 112d is the same as that of the first defect measurement unit 112a, 112b, or 112c. In the second defect measurement unit 112d, a predetermined solution Y is mixed with the resist mixture acquired from the acquisition port α2 and the acquisition port β2. Then, the defects of the mixture mixed with the predetermined solution Y are measured by the FPT method.

The predetermined solution Y is not particularly limited, and at least one solvent selected from the group consisting of, for example, an aprotic polar solvent including tetrahydrofuran (THF), N-methyl-2-pyrrolidone (NMP), N,N-dimethylformamide (DMF), methyl ethyl ketone (MEK), and propylene glycol dimethyl ether (PGME), a protic polar solvent, toluene, and ethyl acetate can be preferably used. For example, the same organic solvent as the organic solvent stored in the container 101 included in the resist mixture may be used as a predetermined solution Y.

The predetermined solution Y may be the solution that differs from the predetermined the solution X or may be the same solution. Here, the predetermined solution X is an example of “the predetermined first solution”, and the predetermined solution Y is an example of “the predetermined second solution”.

For example, if the difference obtained by subtracting the number of third defects from the number of fourth defects is larger than the second predetermined value, the resist mixture filled in the containers 111a, 111b, 1111c, and 111d can be returned to the mixing vessel 100 via the pipe 109c. Here, “the difference obtained by subtracting the number of third defects from the number of fourth defects is larger than the second predetermined value” means that the defects of the resist mixtures are increased by filling the container. According to the method of manufacturing the resist of the present embodiment, the container can be filled again after the resist mixture is returned to the mixing vessel 100 and the defects are reduced even when the defects in the resist mixture are increased by filling the container 111. Note that such an operation can be performed using, for example, the controller 120 (FIG. 2).

In other words, according to the method of manufacturing the resist of the present embodiment, the containers 111a, 111b, 111c, and 111d, which are resist bottles, can be cleaned using the resist mixture for filling. The resist mixture with the increased number of defects by the cleaning is returned to the mixing vessel 100, the number of defects is decreased, and filled into the container.

While certain embodiments and examples have been described, these embodiments and examples have been presented by way of example only, and are not intended to limit the scope of the inventions. Indeed, the novel embodiments described herein may be embodied in a wide variety of other forms; furthermore, various omissions, substitutions and changes in the form of the embodiments described herein may be made without departing from the spirit of the inventions. These embodiments and variations thereof fall within the scope and spirit of the invention, and fall within the scope of the invention described in the claims and equivalents thereof.

The above-described embodiments can be summarized in the following technical proposals.

(Technical Proposal 1) A method of manufacturing a resist, comprising:
obtaining a resist mixture by mixing a raw material of the resist in a mixing vessel;
repeating
   delivering the resist mixture from a bottom of the mixing vessel to an inlet of a filter, the filter including the inlet and an outlet;
   filtering the resist mixture using the filter; and
   delivering the filtered resist mixture from the outlet to the mixing vessel;
obtaining a first mixture by mixing the resist mixture and a predetermined first solution, the resist mixture being obtained from between the bottom and the inlet;
measuring first defects of the first mixture;
obtaining a second mixture by mixing the resist mixture and the predetermined first solution, the resist mixture being obtained from between the outlet and the mixing vessel;
measuring second defects of the second mixture; and
comparing the first defects and the second defects.

(Technical Proposal 2) The method of manufacturing the resist according to technical proposal 1,
wherein comparing the first defects and the second defects includes
when a difference obtained by subtracting the number of the second defects from the number of the first defects is less than or equal to a predetermined first value,
stop repeating
   delivering the resist mixture from the bottom of the mixing vessel to the inlet of the filter, the filter including the inlet and the outlet;
   filtering the resist mixture using the filter; and
   delivering the filtered resist mixture from the outlet to the mixing vessel.

(Technical Proposal 3) The method of manufacturing the resist according to technical proposal 2, further comprising:
stop repeating
   delivering the resist mixture from the bottom of the mixing vessel to the inlet of the filter, the filter including the inlet and the outlet;
   filtering the resist mixture using the filter; and
   delivering the filtered resist mixture from the outlet to the mixing vessel,
and then, filling the filtered resist mixture from the outlet into a container.

(Technical Proposal 4) The method of manufacturing the resist according to technical proposal 3, further comprising:
obtaining a third mixture by mixing the filtered resist mixture and a predetermined second solution;
measuring third defects of the third mixture;
obtaining a fourth mixture by mixing the filled resist mixture and the predetermined second solution;
measuring fourth defects of the fourth mixture; and comparing the third defects and the fourth defects.

(Technical Proposal 5) The method of manufacturing the resist according to technical proposal 4,
wherein comparing the third defects and the fourth defects includes
when a difference obtained by subtracting the number of the third defects from the number of the fourth defects is larger than a second predetermined first value, delivering the filled resist mixture to the mixing vessel.

(Technical Proposal 6) The method of manufacturing the resist according to technical proposal 4,
wherein measuring the third defects includes
delivering the third mixture mixed with the predetermined second solution to a second column, the second column being transparent;
performing a second irradiation to the third mixture in the second column with a second irradiation light;
imaging a second scattered light emitted from the third defects by the second irradiation;
obtaining a second diffusion coefficient of the third defects from the imaged second scattered light;
calculating a second particle size and a second refractive index of the third defects using the second diffusion coefficient; and
determining whether the third defects contain
   a first particle containing metal, or
   a bubble or a second particle, the second particle being different from the bubble and the first particle.

(Technical Proposal 7) The method of manufacturing the resist according to technical proposal 4,
wherein the predetermined first solution and the predetermined second solution are the same solution.

(Technical Proposal 8) The method of manufacturing the resist according to technical proposal 1,
wherein measuring the first defects includes
delivering the first mixture mixed with the predetermined first solution to a first column, the first column being transparent;
performing a first irradiation to the first mixture in the first column with a first irradiation light;
imaging a first scattered light emitted from the first defects by the first irradiation;
obtaining a first diffusion coefficient of the first defects from the imaged first scattered light;
calculating a first particle size and a first refractive index of the first defects using the first diffusion coefficient; and
determining whether the first defects contain
   a first particle containing metal, or
   a bubble or a second particle, the second particle being different from the bubble and the first particle.

(Technical Proposal 9) The method of manufacturing the resist according to technical proposal 8,
wherein measuring the first defects further includes
measuring the first defects of the first mixture irradiated with the first irradiation light using SP-ICP-MS method.

(Technical Proposal 10) The method of manufacturing the resist according to technical proposal 8,
wherein the first defects of the first mixture are measured using SP-ICP-MS method.

(Technical Proposal 11) The method of manufacturing the resist according to technical proposal 1,
wherein the raw material contains at least one compound selected from the group consisting of pyrazine-based, thiophene-based, fullerene-based, adamantane-based, heterocyclic ring system, and fluorinated system.

(Technical Proposal 12) The method of manufacturing the resist according to technical proposal 1,
wherein the raw material contains at least one compound selected from the group consisting of a bromine compound, a halogen compound including an iodine compound and a fluorine compound, and phenols.

(Technical Proposal 13) The method of manufacturing the resist according to technical proposal 1,
wherein the predetermined first solution contains at least one solution selected from the group consisting of tetrahydrofuran (THF), N-methyl-2-pyrrolidone (NMP), N,N-dimethylformamide (DMF), methyl ethyl ketone (MEK), and propylene glycol dimethyl ether (PGME), protic polar solvent, toluene, and ethyl acetate.

(Technical Proposal 14) The method of manufacturing the resist according to technical proposal 1,
wherein the resist mixture and the predetermined first solution are mixed using a static mixer.

While certain embodiments have been described, these embodiments have been presented by way of example only, and are not intended to limit the scope of the inventions. Described herein may be embodied in a variety of other forms; furthermore, various omissions, substitutions and changes in the form of the devices and methods described herein may be made without departing from the spirit of the inventions, for manufacturing Indeed, resists The accompanying claims and their equivalents are intended to cover such forms or modifications as would fall within the scope and spirit of the inventions.

What is claimed is:

1. A method of manufacturing a resist, comprising:
obtaining a resist mixture by mixing a raw material of the resist in a mixing vessel;
repeating
delivering the resist mixture from a bottom of the mixing vessel to an inlet of a filter, the filter including the inlet and an outlet;
filtering the resist mixture using the filter; and
delivering the filtered resist mixture from the outlet to the mixing vessel;
obtaining a first mixture by mixing the resist mixture and a predetermined first solution, the resist mixture being obtained from between the bottom and the inlet;
measuring first defects of the first mixture;
obtaining a second mixture by mixing the resist mixture and the predetermined first solution, the resist mixture being obtained from between the outlet and the mixing vessel;
measuring second defects of the second mixture; and
comparing the first defects and the second defects.

2. The method of manufacturing the resist according to claim 1,
wherein comparing the first defects and the second defects includes
when a difference obtained by subtracting the number of the second defects from the number of the first defects is less than or equal to a predetermined first value,
stop repeating
delivering the resist mixture from the bottom of the mixing vessel to the inlet of the filter, the filter including the inlet and the outlet;
filtering the resist mixture using the filter; and
delivering the filtered resist mixture from the outlet to the mixing vessel.

3. The method of manufacturing the resist according to claim 2, further comprising:
stop repeating
delivering the resist mixture from the bottom of the mixing vessel to the inlet of the filter, the filter including the inlet and the outlet;
filtering the resist mixture using the filter; and
delivering the filtered resist mixture from the outlet to the mixing vessel,
and then, filling the filtered resist mixture from the outlet into a container.

4. The method of manufacturing the resist according to claim 3, further comprising:
obtaining a third mixture by mixing the filtered resist mixture and a predetermined second solution;
measuring third defects of the third mixture;
obtaining a fourth mixture by mixing the filled resist mixture and the predetermined second solution;
measuring fourth defects of the fourth mixture; and
comparing the third defects and the fourth defects.

5. The method of manufacturing the resist according to claim 4,
wherein comparing the third defects and the fourth defects includes
when a difference obtained by subtracting the number of the third defects from the number of the fourth defects is larger than a second predetermined first value, delivering the filled resist mixture to the mixing vessel.

6. The method of manufacturing the resist according to claim 4,
wherein measuring the third defects includes
delivering the third mixture mixed with the predetermined second solution to a second column, the second column being transparent;
performing a second irradiation to the third mixture in the second column with a second irradiation light;
imaging a second scattered light emitted from the third defects by the second irradiation;
obtaining a second diffusion coefficient of the third defects from the imaged second scattered light;
calculating a second particle size and a second refractive index of the third defects using the second diffusion coefficient; and
determining whether the third defects contain
a first particle containing metal, or
a bubble or a second particle, the second particle being different from the bubble and the first particle.

7. The method of manufacturing the resist according to claim 4,
wherein the predetermined first solution and the predetermined second solution are the same solution.

8. The method of manufacturing the resist according to claim 1,
wherein measuring the first defects includes
delivering the first mixture mixed with the predetermined first solution to a first column, the first column being transparent;
performing a first irradiation to the first mixture in the first column with a first irradiation light;
imaging a first scattered light emitted from the first defects by the first irradiation;
obtaining a first diffusion coefficient of the first defects from the imaged first scattered light;
calculating a first particle size and a first refractive index of the first defects using the first diffusion coefficient; and
determining whether the first defects contain
a first particle containing metal, or
a bubble or a second particle, the second particle being different from the bubble and the first particle.

9. The method of manufacturing the resist according to claim 8,
wherein measuring the first defects further includes
measuring the first defects of the first mixture irradiated with the first irradiation light using SP-ICP-MS method.

10. The method of manufacturing the resist according to claim 8,
wherein the first defects of the first mixture are measured using SP-ICP-MS method.

11. The method of manufacturing the resist according to claim 1,
wherein the raw material contains at least one compound selected from the group consisting of pyrazine-based, thiophene-based, fullerene-based, adamantane-based, heterocyclic ring system, and fluorinated system.

12. The method of manufacturing the resist according to claim 1,
wherein the raw material contains at least one compound selected from the group consisting of a bromine compound, a halogen compound including an iodine compound and a fluorine compound, and phenols.

13. The method of manufacturing the resist according to claim 1,
wherein the predetermined first solution contains at least one solution selected from the group consisting of tetrahydrofuran (THF), N-methyl-2-pyrrolidone (NMP) N,N-dimethylformamide (DMF), methyl ethyl ketone (MEK) and propylene glycol dimethyl ether (PGME), protic polar solvent, toluene, and ethyl acetate.

14. The method of manufacturing the resist according to claim 1,
wherein the resist mixture and the predetermined first solution are mixed using a static mixer.
